(19) United States
(12) Patent Application Publication
(10) Pub. No.: US 2025/0301817 A1
(43) Pub. Date: Sep. 25, 2025

(54) LIGHT RECEIVING DEVICE

(71) Applicant: DEXERIALS CORPORATION, Tochigi (JP)

(72) Inventor: Yu ITAZAKI, Tochigi (JP)

(21) Appl. No.: 19/082,572

(22) Filed: Mar. 18, 2025

(30) Foreign Application Priority Data
Mar. 21, 2024 (JP) 2024-045284

(51) Int. Cl. H10F 77/14; H10F 30/22; H10F 39/90; H10F 77/00

(52) U.S. Cl. CPC H10F 77/147; H10F 30/22; H10F 39/90; H10F 77/933

(57) ABSTRACT

A light receiving device includes a first light-receiving element and a second light-receiving element, each including a semiconductor substrate including a light receiving region, and a support substrate including a supporting surface supporting the first light-receiving element and the second light-receiving element. The semiconductor substrate of the first or second light-receiving element includes a main surface including the light receiving region, a back surface on an opposite side of the main surface in a perpendicular direction, and a recess sunk from the back surface towards the main surface. The other semiconductor substrate of the first light-receiving element or second light-receiving element is disposed inside the recess. An angle θ formed between a side surface of the recess and the supporting surface is 75° or greater and 105° or less, where the side surface is continuous from an opening edge of the recess to a bottom surface of the recess.

### CROSS-REFERENCE TO RELATED APPLICATIONS

This application is based on and claims priority to Japanese Patent Application No. 2024-045284 filed on Mar. 21, 2024, the contents of which are incorporated herein by reference in its entirety.

### BACKGROUND

### 1. Field of the Invention

The present disclosure relates to light receiving devices.

### 2. Description of the Related Art

There has been known a light receiving device including light-receiving elements respectively receiving different types of light having mutually different wavelength bands (see, for example, Japanese Unexamined Patent Application Publication No. 2019-12713). In the light receiving device disclosed in Japanese Unexamined Patent Application Publication No. 2019-12713, the light-receiving elements are stacked.

### SUMMARY

According to one aspect of the present disclosure, a light receiving device includes a first light-receiving element that includes a semiconductor substrate including a light receiving region, a second light-receiving element that includes a semiconductor substrate including a light receiving region, and a support substrate that includes a supporting surface supporting the first light-receiving element and the second light-receiving element. The semiconductor substrate of the first light-receiving element or the second light-receiving element includes a main surface including the light receiving region, a back surface that is on an opposite side of the main surface in a perpendicular direction, and a recess that is sunk from the back surface towards the main surface. The other semiconductor substrate of the first light-receiving element or the second light-receiving element is disposed inside the recess. An angle θ formed between a side surface of the recess and the supporting surface is 75° or greater and 105° or less, where the side surface is a surface continuous from an opening edge of the recess to a bottom surface of the recess.

### BRIEF DESCRIPTION OF THE DRAWINGS

FIG. 1 is a plan view schematically illustrating an example of the light receiving device according to a first embodiment;

FIG. 2 is a cross-sectional view illustrating a schematic cross-section of the light receiving device according to the first embodiment cut along the line II-II of FIG. 1;

FIG. 3 is a cross-sectional view illustrating a schematic cross-section of the light receiving device cut along the plane XZ, when an angle θ formed between a side surface of a recess and a supporting surface of a support substrate is 75° or greater and 90° or less in the first embodiment;

FIG. 4 is a cross-sectional view illustrating a schematic cross-section of the light receiving device cut along the plane XZ, when the angle θ formed between the side surface of the recess and the supporting surface of the support substrate is 90° or greater and 105° or less in the first embodiment;

FIG. 5 is a cross-sectional view illustrating a schematic cross-section of the light receiving device according to Modification Example 1 of the first embodiment, which is cut along the plane XZ;

FIG. 6 is a plan view schematically illustrating the light receiving device according to Modification Example 2 of the first embodiment;

FIG. 7 is a cross-sectional view illustrating a schematic cross-section of the light receiving device according to Modification Example 2 of the first embodiment, which is cut along the line VII-VII of FIG. 6;

FIG. 8 is a cross-sectional view illustrating a schematic cross-section of the light receiving device according to Modification Example 2 of the first embodiment, which is cut along the line VIII-VIII of FIG. 6;

FIG. 9 is a plan view schematically illustrating an example of the light receiving device according to a second embodiment; and

FIG. 10 is a cross-sectional view illustrating a schematic cross-section of the light receiving device according to the second embodiment, which is cut along the line X-X of FIG. 9.

### DETAILED DESCRIPTION

The thickness of the light receiving device disclosed in Japanese Unexamined Patent Application Publication No. 2019-12713 increases according to the thicknesses of the light-receiving elements. Therefore, there is scope for improvement in downsizing of the light receiving device.

One aspect of the present disclosure aims to provide a light receiving device that is downsized.

Embodiments of the present disclosure will be described in detail hereinafter. In order to facilitate understanding of the description, the same constituent components are denoted by the same reference numerals in the drawings, and redundant description will be appropriately omitted. Moreover, a scale of each member in the drawings may be different from an actual scale.

In the drawings, directions may be indicated by an X axis, a Y axis, and a Z axis. The X axis, the Y axis, and the Z axis indicate directions that are orthogonal to one another. The direction in which an arrow points in the X-axial direction is denoted as a +X direction or +X side, and the opposite direction to the +X direction is denoted as a −X direction or −X side. The direction in which an arrow points in the Y-axial direction is denoted as a +Y direction or +Y side, and the opposite direction to the +Y direction is denoted as a −Y direction or −Y side. The direction in which an arrow points in the Z-axial direction is denoted as a +Z direction or +Z side, and the opposite direction to the +Z direction is denoted as a −Z direction or −Z side.

In the following embodiments, “parallel” to the X axis, the Y axis, the Z axis, and any other directions includes an error in a range in which a subject is inclined by ±5° with respect to the above axes or directions. In the embodiments, the term “orthogonal” includes an error within ±5° with respect to 90°. Further, the direction parallel to the X-axial direction and the Y-axial direction may be referred to as a “planar direction.” The direction parallel to the Z-axial direction may be referred to as a “perpendicular direction.” The planar direction and the perpendicular direction are orthogonal to each other.

### First Embodiment

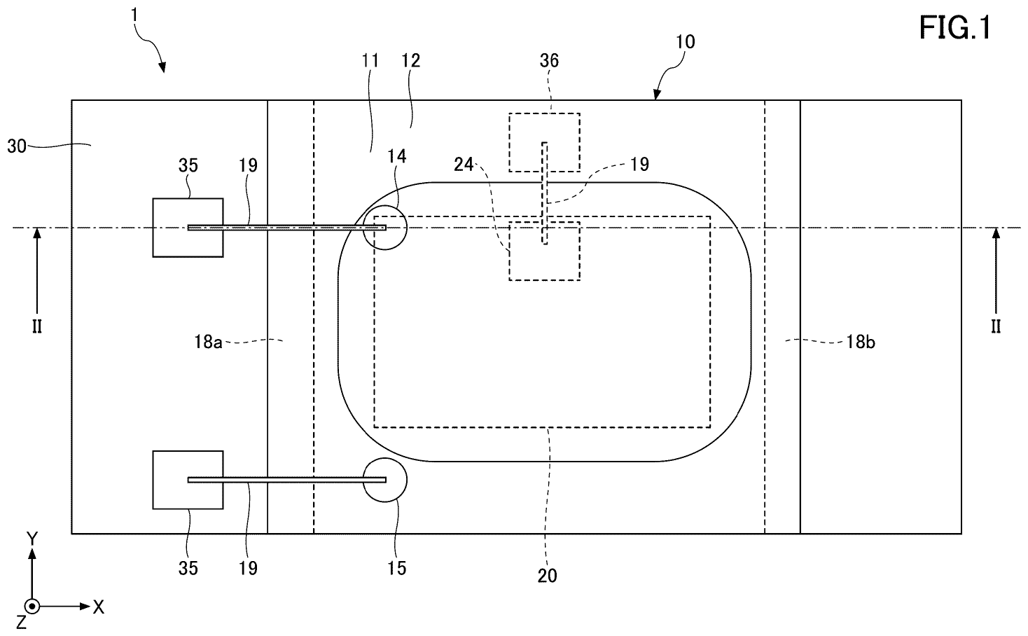

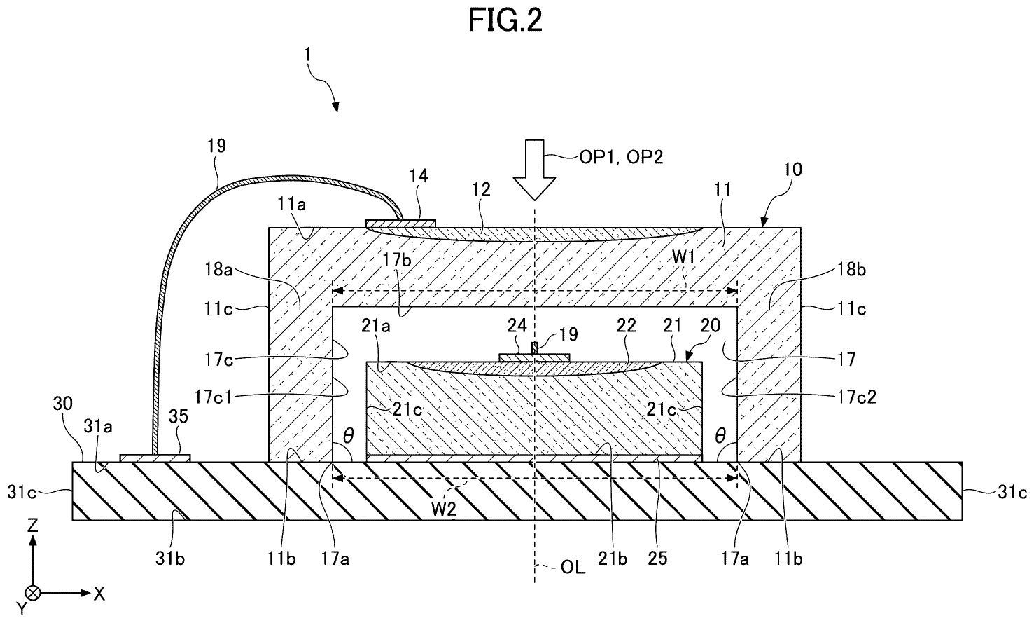

One example of a configuration of the light receiving device 1 according to the first embodiment will be described with reference to FIGS. 1 and 2. FIG. 1 is a plan view schematically illustrating an example of the light receiving device 1 according to the first embodiment. FIG. 2 is a cross-sectional view illustrating a schematic cross-section of the light receiving device 1 cut along the line II-II of FIG. 1. FIG. 2 illustrates an example of the cross-sectional view of the light receiving device 1 cut in the perpendicular direction to include a recess 17 of a first light-receiving element 10, which will be described later.

As illustrated in FIGS. 1 and 2, the light receiving device 1 according to the first embodiment includes a first light-receiving element 10, a second light-receiving element 20, and a support substrate 30. The light receiving device 1 may further include an optical film, such as an antireflection film for inhibiting reflection of light, or the like.

### First Light-Receiving Element 10

One example of a configuration of the first light-receiving element 10 will be described. The first light-receiving element 10 is, for example, a photoelectric conversion element, such as a photodiode or the like. The first light-receiving element 10 includes a first semiconductor substrate 11. The first semiconductor substrate 11 is an example of the “semiconductor substrate of the first light-receiving element or the second light-receiving element.” As illustrated in FIG. 1, the first semiconductor substrate 11 has a substantially rectangular shape in a plan view. As illustrated in FIG. 2, the first semiconductor substrate 11 includes a main surface 11a, a back surface 11b, and side surfaces 11c.

In the example illustrated in FIG. 2, the main surface 11a is a surface of the first semiconductor substrate 11 on the +Z side. The light OP1 to be received by the first light-receiving element 10 enters from the main surface 11a. An antireflection film is preferably disposed on the main surface 11a. A thickness and material of the antireflection film may be appropriately selected. The back surface 11b is a surface that is on an opposite side of the main surface 11a in the perpendicular direction. Specifically, the back surface 11b corresponds to a surface of the first semiconductor substrate 11 on the −Z side. Each side surface 11c connects an outer edge of the main surface 11a and an outer edge of the back surface 11b.

The first semiconductor substrate 11 is composed of a semiconductor material having a larger band gap than a material constituting a second semiconductor substrate 21 of the second light-receiving element 20, which will be described later. For example, the first semiconductor substrate 11 receives visible light. Examples of the material constituting the first semiconductor substrate 11 include silicon (Si). The material constituting the first semiconductor substrate 11 is not limited to Si. The first semiconductor substrate 11 has n-type conductivity except a light receiving region 12, which will be described later.

The first semiconductor substrate 11 includes the light receiving region 12. As illustrated in FIGS. 1 and 2, the light receiving region 12 is included in the main surface 11a of the first semiconductor substrate 11. The light receiving region 12 corresponds to, for example, a p-type diffusion region doped with an acceptor element, such as boron. An interface between the light receiving region 12 and a remaining region other than the light receiving region 12 in the first semiconductor substrate 11 corresponds to a p-n junction region. The light OP1 that has reached the p-n junction region is converted into charges.

The charges generated in the p-n junction region in response to receipt of the light OP1 are, for example, extracted as a current to the outside via an anode 14 and a cathode 15 both disposed on the main surface 11a of the first semiconductor substrate 11. Specifically, a light receiving signal from the first light-receiving element 10 is output to the outside via the anode 14 and the cathode 15. In the example illustrated in FIGS. 1 and 2, the light receiving signal from the first light-receiving element 10 is output to the wiring 35 of the support substrate 30. The anode 14 is coupled to the light receiving region 12. The cathode 15 is coupled to the remaining region of the first semiconductor substrate 11 other than the light receiving region 12.

As illustrated in FIG. 2, the first semiconductor substrate 11 further includes a recess 17. The recess 17 corresponds to a hollow space within the first semiconductor substrate 11, which is sunk from the back surface 11b toward the main surface 11a. In the example illustrated in FIG. 2, the recess 17 includes opening edges 17a on the back surface 11b side of the first semiconductor substrate 11, a bottom surface 17b that is on the +Z side with respect to the opening edges 17a, and side surfaces 17c each being continuous from the opening edge 17a to the bottom surface 17b.

The recess 17 may be formed, for example, by dry etching, a combination of dry etching and wet etching, or machining using a cutting tool, such as a blade or the like. In the first semiconductor substrate 11, wall-like portions positioned on sides of the recess 17 are formed corresponding to the shape of the recess 17. Each wall-like portion may be referred to as a “side wall” of the first semiconductor substrate 11 hereinafter.

In the example illustrated in FIGS. 1 and 2, the first semiconductor substrate 11 includes, as side walls, a first side wall 18a on the −X side and a second side wall 18b on the +X side. Specifically, in the example illustrated in FIGS. 1 and 2, the first semiconductor substrate 11 includes two side walls. The first side wall 18a and the second side wall 18b face each other with the recess 17 being interposed between the first side wall 18a and the second side wall 18b in the X-axial direction. The recess 17 illustrated in FIGS. 1 and 2 has a gutter-like shape extending in the Y-axial direction, and the gutter-like shape is defined by the first side wall 18a and the second side wall 18b. Specifically, the both ends of the recess 17 in the Y-axial direction are open. The number of the side walls is not limited to two. The number of the side walls may be three or four.

The opening edges 17a are defined by the inner edges of the back surface 11b of the first semiconductor substrate 11. The bottom surface 17b is defined by a bottom inner surface of the first semiconductor substrate 11. The bottom surface 17b is, for example, a surface extending in the planar direction. An antireflection film is preferably disposed on the bottom surface 17b. In the example illustrated in FIG. 2, the side surfaces 17c include a first side surface 17c1 on the −X side, and a second side surface 17c2 on the +X side. The first side surface 17c1 is defined by the inner surface of the first side wall 18a of the first semiconductor substrate 11. The second side surface 17c2 is defined by the inner surface of the second side wall 18b of the first semiconductor substrate 11.

As illustrated in FIG. 2, a ratio W1/W2 of W1 to W2 is preferably 0.9 or greater, where W1 is a length of the bottom surface 17b and W2 is a length between the opposing opening edges 17a in a cross-sectional view including the recess 17. W1/W2 is more preferably 0.95 or greater. W1/W2 is more preferably 1.0 or greater. Also, W1/W2 is preferably 1.1 or less. W1/W2 is more preferably 1.05 or less. Specifically, W1/W2 is preferably 0.9 or greater and 1.1 or less, and more preferably 0.95 or greater and 1.05 or less. In the following description, W1 may be referred to as a “bottom surface width,” and W2 may be referred to as an “opening width.”

When W1/W2 is 1.0, as described later, an angle θ formed between the side surface 17c of the recess 17 and the supporting surface 31a of the support substrate 30 becomes 90°. Specifically, the side surfaces 17c of the recess 17 extend in the perpendicular direction. When W1/W2 is 0.9 or greater and 1.1 or less, moreover, the side surfaces of the recess 17 are in the state in which the side surfaces 17c extend substantially in the perpendicular direction with respect to the supporting surface 31a. Specifically, the side surfaces 17c of the recess 17 are barely inclined. Thus, the first semiconductor substrate 11 can be downsized in the planar direction without reducing the size of the second light-receiving element 20 (second semiconductor substrate 21), which is disposed inside the recess 17, in the planar direction. Thus, the first light-receiving element 10 and the light receiving device 1 can be downsized. In addition, the size of the second light-receiving element 20 (second semiconductor substrate 21) can be increased in the planar direction without increasing the first semiconductor substrate 11 in the planar direction. Thus, the amount of light received by the second light-receiving element 20 can be increased.

### Second Light-Receiving Element 20

One example of a configuration of the second light-receiving element 20 will be described. The second light-receiving element 20 is, for example, a photoelectric conversion element, such as a photodiode or the like. As illustrated in FIGS. 1 and 2, the second light-receiving element 20 is disposed inside the recess 17 of the first semiconductor substrate 11. The second light-receiving element 20 includes a second semiconductor substrate 21. The second semiconductor substrate 21 is an example of “the other semiconductor substrate.”

As illustrated in FIG. 1, the second semiconductor substrate 21 has a substantially rectangular shape in a plan view. As illustrated in FIG. 2, the second semiconductor substrate 21 includes a main surface 21a, a back surface 21b, and side surfaces 21c. In the example illustrated in FIG. 2, the main surface 21a corresponds to a surface of the second semiconductor substrate 21 on the +Z side. Light OP2 to be received by the second light-receiving element 20 enters from the main surface 21a. An antireflection film is preferably disposed on the main surface 21a. The back surface 21b is a surface on the opposite side of the main surface 21a in the perpendicular direction. Specifically, the back surface 21b corresponds to a surface of the second semiconductor substrate 21 on the −Z side. The side surface 21c connects between an outer edge of the main surface 21a and an outer edge of the back surface 21b.

The second semiconductor substrate 21 is composed of a semiconductor material having a smaller band gap than a material constituting the first semiconductor substrate 11. For example, the second semiconductor substrate 21 receives infrared light. Examples of the material constituting the second semiconductor substrate 21 include indium phosphide (InP). However, the material constituting the second semiconductor substrate 21 is not limited to InP. The second semiconductor substrate 21 has n-type conductivity except a light receiving region 22, which will be described later.

The second semiconductor substrate 21 includes the light receiving region 22. As illustrated in FIGS. 1 and 2, the light receiving region 22 is included in the main surface 21a of the second semiconductor substrate 21. In the example illustrated in FIG. 2, the main surface 21a of the second semiconductor substrate 21, in which the light receiving region 22 is included, is on the +Z side. However, the main surface 21a may be disposed on the −Z side. In this case, the back surface 21b of the second semiconductor substrate 21 is on the +Z side with respect to the main surface 21a.

The light receiving region 22 is arranged in a position overlapping the light receiving region 12 of the first semiconductor substrate 11 in a plan view. Thus, the light receiving region 22 can be arranged to be intersecting the optical axis OL of the light OP1 entering the light receiving region 12. As a result, the second light-receiving element 20 can be disposed inside the recess 17 of the first semiconductor substrate 11 and can be arranged to align with the first light-receiving element 10 in the Z-axial direction. Specifically, the thickness of the light receiving device 1 does not exceed the thickness of the first light-receiving element 10 even when the first light-receiving element 10 and the second light-receiving element 20 are aligned in the Z-axial direction. Thus, the light receiving device 1 can be downsized.

The light receiving region 22 corresponds to a region having p-type conductivity, which is composed of indium gallium arsenide (InGaAs). The interface between the light receiving region 22 and the remaining region other than the light receiving region 22 in the second semiconductor substrate 21 corresponds to a p-n junction region. The light OP2 that has reached the p-n junction region is converted into charges.

The charges generated in the p-n junction region in response to receipt of the light OP2 are, for example, extracted as a current to the outside via an anode 24 and a cathode 25 of the second semiconductor substrate 21. Specifically, a light receiving signal from the second light-receiving element 20 is output to the outside via the anode 24 and the cathode 25. In the example illustrated in FIGS. 1 and 2, the light receiving signal from the second light-receiving element 20 is output to the wiring 36 of the support substrate 30. The anode 24 is coupled to the light receiving region 22. The cathode 25 is coupled to the remaining region other than the light receiving region 22 in the second semiconductor substrate 21.

### Support Substrate 30

Next, one example of a configuration of the support substrate 30 will be described. The support substrate 30 supports the first light-receiving element 10 and the second light-receiving element 20. Moreover, the support substrate 30 may be a wiring board for transmitting light receiving signals, which are output respectively from the first light-receiving element 10 and the second light-receiving element 20, to the outside. In the example illustrated in FIGS. 1 and 2, the support substrate 30 includes the wiring 35 coupled to the anode 14 and the cathode 15 of the first light-receiving element 10, respectively, and the wiring 36 coupled to the anode 24 and the cathode 25 of the second light-receiving element 20, respectively. The wiring 35 is coupled to the anode 14 and the cathode 15 via a conductive wire, such as a bonding wire 19, respectively. The wiring 36 is coupled to the anode 24 via a conductive wire, such as a bonding wire 19. Although the wiring coupled to the cathode 25 of the second light-receiving element 20 is not illustrated, the wiring may be coupled to the cathode 25, for example, via a wire disposed in another position of the support substrate 30. The wirings included in the support substrate 30, such as the wiring 35, the wiring 36, and the like, are coupled to, for example, an external signal processing circuit.

As illustrated in FIG. 1, the support substrate 30 has a substantially rectangular shape in a plan view. As illustrated in FIG. 2, the support substrate 30 includes a main surface 31a, a back surface 31b, and side surfaces 31c. The main surface 31a corresponds to a surface of the support substrate 30 on the +Z side. The main surface 31a is a surface that supports the first light-receiving element 10 and the second light-receiving element 20. The main surface 31a may be referred to as a “supporting surface 31a” hereinafter. The back surface 31b is a surface that is on an opposite side of the supporting surface 31a in the perpendicular direction. Specifically, the back surface 31b corresponds to a surface of the support substrate 30 on the −Z side. The side surface 31c connects an outer edge of the supporting surface 31a and an outer edge of the back surface 31b.

Examples of a material constituting the support substrate 30 include glass epoxy, ceramics, and resins. The material constituting the support substrate 30 is not limited to the above-listed examples.

### Angle θ Formed Between Side Surface 17c of Recess 17 and Supporting Surface 31a of Support Substrate 30

Next, the angle θ formed between the side surface 17c of the recess 17 and the supporting surface 31a of the support substrate 30 will be described. In the example illustrated in FIG. 2, the angle θ corresponds to an angle between the first side surface 17c1 of the recess 17 and the supporting surface 31a, and to an angle between a second side surface 17c2 of the recess 17 and the supporting surface 31a. The angle θ between the first side surface 17c1 of the recess 17 and the supporting surface 31a is an example of an “angle θ1.” The angle θ between the second side surface 17c2 of the recess 17 and the supporting surface 31a is an example of an “angle θ2.”

The angle θ between the first side surface 17c1 of the recess 17 and the supporting surface 31a and the angle θ between the second side surface 17c2 of the recess 17 and the supporting surface 31a may be the same or different from each other. However, each angle θ satisfies the conditions associated with the angle θ, which will be described later. The description will be made hereinafter with assumption that the angle θ between the first side surface 17c1 of the recess 17 and the supporting surface 31a and the angle θ between the second side surface 17c2 of the recess 17 and the supporting surface 31a are the same.

The angle θ is 75° or greater and 105° or less. The angle θ is preferably 80° or greater and 100° or less. The angle θ is more preferably 85° or greater and 95° or less. Further, the angle θ is yet more preferably 90°. Since the angle θ is 75° or greater and 105° or less, the side surface 17c of the recess 17 can be in the state where the side surface 17c extends substantially in the perpendicular direction. Specifically, the side surface 17c of the recess 17 can be in the state in which the side surface 17c is barely inclined. Thus, the size of the first semiconductor substrate 11 in the planar direction can be reduced without reducing the size of the second semiconductor substrate 21 in the planar direction. As a result, the first light-receiving element 10 and the light receiving device 1 can be downsized. In addition, the size of the second semiconductor substrate 21 in the planar direction can be increased without increasing the size of the first semiconductor substrate 11 in the planar direction. Thus, the light receiving region 22 of the second semiconductor substrate 21 can be increased, thereby increasing an amount of light received by the second light-receiving element 20.

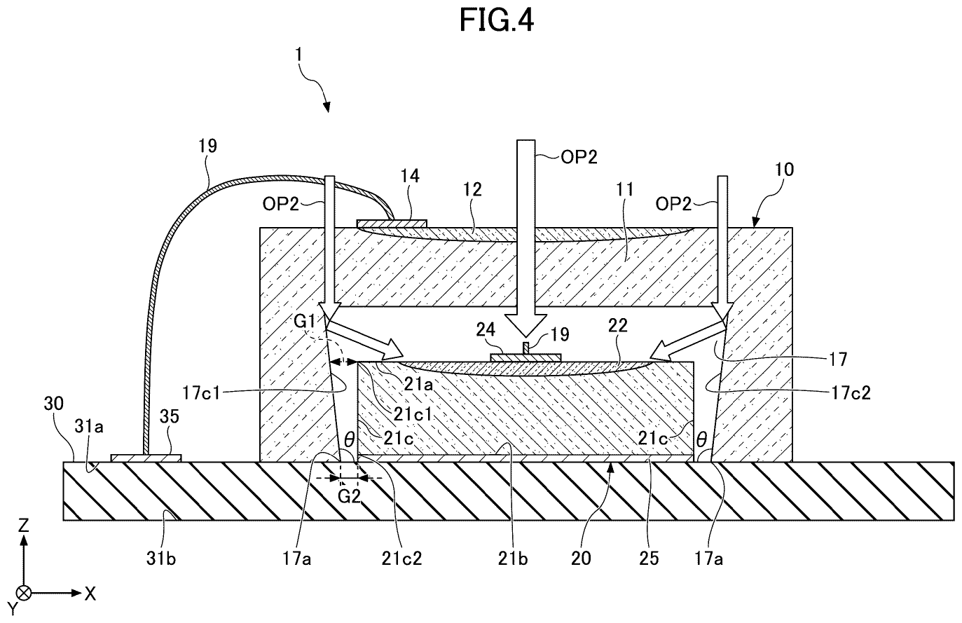

When the angle θ is 90° or greater and 105° or less, moreover, the light OP2 reflected by the side surface 17c of the recess 17 can be incident on the light receiving region 22 of the second semiconductor substrate 21 (see FIG. 4). The above configuration can also increase the amount of light received by the second light-receiving element 20.

### Gap Between Recess 17 of First Semiconductor Substrate 11 and Second Semiconductor Substrate 21

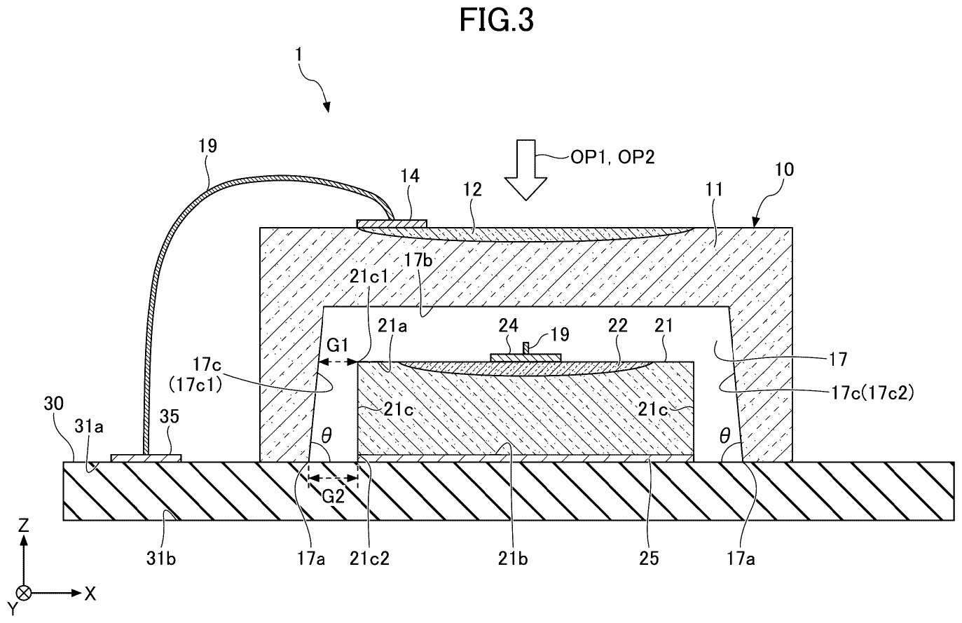

Next, the gap between the recess 17 of the first semiconductor substrate 11 and the second semiconductor substrate 21 will be described with reference to FIGS. 3 and 4. FIG. 3 is a cross-sectional view illustrating a schematic cross-section of the light receiving device 1 cut along the plane XZ when the angle θ formed between the side surface 17c of the recess 17 and the supporting surface 31a is 75° or greater and 90° or less. FIG. 4 is a cross-sectional view illustrating a schematic cross-section of the light receiving device 1 cut along the plane XZ when the angle θ formed between the side surface 17c of the recess 17 and the supporting surface 31a is 90° or greater and 105° or less. FIGS. 3 and 4 are examples of the cross-sectional views of the light receiving device 1 cut in the perpendicular direction to include the recess 17.

As illustrated in FIGS. 3 and 4, in the cross-sectional view of the light receiving device 1 cut in the perpendicular direction to include the recess 17, the gap “G1” corresponds to a gap between an end 21c1 of the side surface 21c of the second semiconductor substrate 21 on the main surface 21a side and the side surface 17c of the recess 17. The gap G1 is, for example, a gap between the end 21c1 of the side surface 21c of the second semiconductor substrate 21 on the −X side and a point of intersection, which is an intersection of a line extending from the end 21c1 in the planar direction with the first side surface 17c1 of the recess 17.

As illustrated in FIGS. 3 and 4, in the cross-sectional view of the light receiving device 1 cut in the perpendicular direction to include the recess 17, the gap “G2” corresponds to a gap between the end 21c2 of the side surface 17c of the second semiconductor substrate 21 on the back surface 21b side and the side surface 17c of the recess 17. The gap G2 is, for example, a gap between the end 21c2 of the side surface 21c of the second semiconductor substrate 21 on the −X side and a point of intersection, which is an intersection of the line extending from the end 21c2 in the planar direction with the first side surface 17c1 of the recess 17.

When the angle θ formed between the side surface 17c of the recess 17 and the supporting surface 31a is 75° or greater and 90° or less, as illustrated in FIG. 3, a ratio G1/G2 of the gap G1 to the gap G2 is preferably 0.9 or greater and 1.0 or less. When the angle θ between the side surface 17c of the recess 17 and the supporting surface 31a is 90° or greater and 105° or less, as illustrated in FIG. 4, G1/G2 is preferably 1 or greater and 1.1 or less. Specifically, G1/G2 is preferably 0.9 or greater and 1.1 or less.

Since G1/G2 is 0.9 or greater and 1.1 or less, the size of the first semiconductor substrate 11 in the planar direction can be reduced without reducing the size of the second semiconductor substrate 21 in the planar direction. As a result, the first light-receiving element 10 and the light receiving device 1 can be downsized. In addition, the size of the second semiconductor substrate 21 in the planar direction can be increased without increasing the size of the first semiconductor substrate 11 in the planar direction. Thus, the light receiving region 22 of the second semiconductor substrate 21 can be increased, thereby increasing an amount of light received by the second light-receiving element.

### Comparison With Comparative Examples

Next, advantageous effects of the light receiving device 1 as compared with Comparative Examples 1 and 2 will be described hereinafter. First, the comparison with Comparative Example 1 will be described. Comparative Example 1 is an example in which the angle θ formed between the side surface 17c of the recess 17 and the supporting surface 31a is 70°. In other words, Comparative Example 1 is an example in which the ratio W1/W2 of the bottom surface width W1 of the recess 17 to the opening width W2 of the recess 17 is 0.8. The other configurations of Comparative Example 1 are the same as the configurations of the light receiving device 1.

Since the angle θ formed between the side surface 17c of the recess 17 and the supporting surface 31a is 70° in Comparative Example 1, inclination of the side surface 17c of the recess 17 with respect to the supporting surface 31a is relatively large. Thus, the side surface 17c of the recess 17 and the second semiconductor substrate 21 of the second light-receiving element 20 are in contact with each other, if the side surface 17c of the recess 17 and the second semiconductor substrate 21 of the second light-receiving element 20 are close to each other. In order to avoid the contact between the side surface 17c of the recess 17 and the second semiconductor substrate 21 of the second light-receiving element 20, the opening width W2 of the recess 17 may be increased, or the size of the second semiconductor substrate 21 may be reduced. As a result, the size of the first semiconductor substrate 11 is increased, or the size of the semiconductor substrate 21 is reduced. In addition, the volume of the space between the side surface 17c of the recess 17 and the second semiconductor substrate 21 is increased. Specifically, the volume of the internal space of the recess 17 that is not occupied by the second light-receiving element 20 is increased. Therefore, Comparative Example 1 has scope for improvement from the viewpoint of space-saving of the recess 17. Conversely, the angle θ formed between the side surface 17c of the recess 17 and the supporting surface 31a in the light receiving device 1 is 75° or greater and 105° or less, and therefore the side surface 17c of the recess 17 is barely inclined with respect to the supporting surface 31a. Thus, the size of the second semiconductor substrate 21 in the planar direction can be increased without increasing the size of the first semiconductor substrate 11 in the planar direction. In addition, an excessive increase in the volume of the internal space of the recess 17 that is not occupied by the second light-receiving element 20 can be avoided.

Next, the comparison with Comparative Example 2 will be described. Comparative Example 2 is an example in which the angle θ formed between the side surface 17c of the recess 17 and the supporting surface 31a is 110°. In other words, Comparative Example 2 is an example in which a ratio W1/W2 of the bottom width W1 of the recess 17 to the opening width W2 of the recess 17 is 1.2. The other configurations of Comparative Example 2 are the same as the configurations of the light receiving device 1.

In Comparative Example 2, the bottom surface width W1 of the recess 17 is greater than the opening width W2 of the recess 17. Moreover, since the angle θ formed between the side surface 17c of the recess 17 and the supporting surface 31a is 110° in Comparative Example 2, inclination of the side surface 17c of the recess 17 with respect to the supporting surface 31a is relatively large. Thus, the side surface 17c of the recess 17 and the second semiconductor substrate 21 of the second light-receiving element 20 are in contact with each other, if the side surface 17c of the recess 17 and the second semiconductor substrate 21 of the second light-receiving element 20 are close to each other. In order to avoid the contact between the side surface 17c of the recess 17 and the second semiconductor substrate 21 of the second light-receiving element 20, the bottom surface width W1 of the recess 17 may be increased, or the size of the second semiconductor substrate 21 in the planar direction may be reduced. As a result, the size of the first semiconductor substrate 11 is increased, or an amount of light received by the second light-receiving element 20 is reduced due to the reduction in the size of the second semiconductor substrate 21. In addition, the volume of the space between the side surface 17c of the recess 17 and the second semiconductor substrate 21 is increased. Specifically, the volume of the internal space of the recess 17 that is not occupied by the second light-receiving element 20 is increased. Therefore, Comparative Example 2 has scope for improvement from the viewpoint of space-saving of the recess 17. Conversely, the angle θ formed between the side surface 17c of the recess 17 and the supporting surface 31a is 75° or greater and 105° or less in the light receiving device 1, and the side surface 17c of the recess 17 is barely inclined with respect to the supporting surface 31a, thus the size of the second semiconductor substrate 21 in the planar direction can be increased without increasing the size of the first semiconductor substrate 11 in the planar direction. In addition, an excessive increase in the volume of the internal space of the recess 17 that is not occupied by the second light-receiving element 20 can be avoided.

Since the bottom surface width W1 of the recess 17 is greater than the opening width W2 of the recess 17 in Comparative Example 2, it is difficult to form the recess 17 having such shape by etching or machining. Conversely, the length of the bottom surface width W1 and the length of the opening width W2 are substantially the same in the recess 17 of the light receiving device 1, and therefore the recess 17 can be easily formed. Thus, the cost of forming the recess 17 in the light receiving device 1 can be reduced.

### Modification Example 1

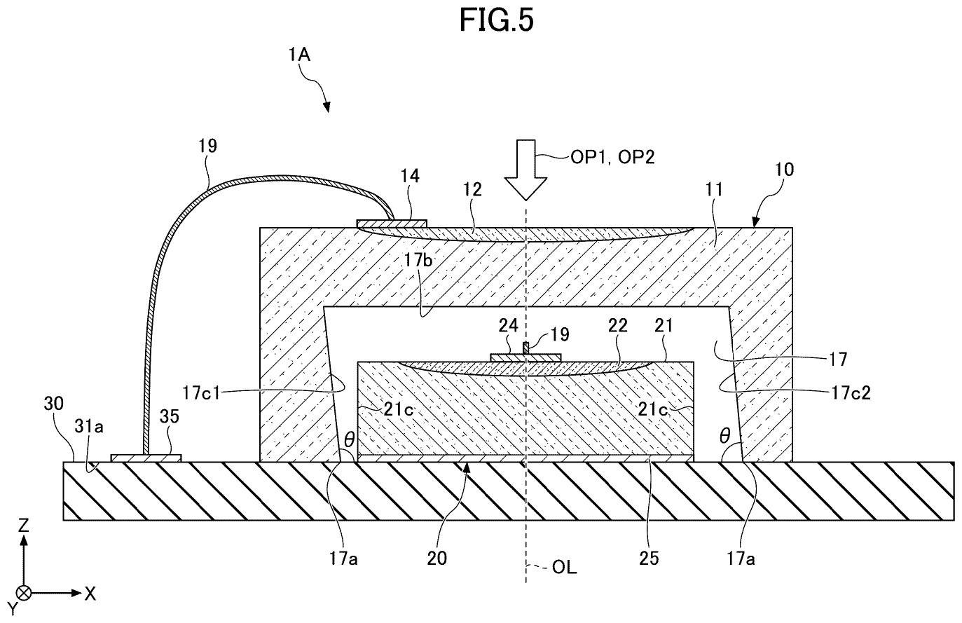

Next, the light receiving device 1A according to Modification Example 1 of the first embodiment will be described with reference to FIG. 5. FIG. 5 is a cross-sectional view illustrating a schematic cross-section of the light receiving device 1A according to Modification Example 1, which is cut along the plane XZ. Note that the same reference numerals are given to the same constituent components as the constituent components in the first embodiment, and redundant description will be appropriately omitted. FIG. 5 is one example of a cross-sectional view of the light receiving device 1A cut in the perpendicular direction to include the recess 17.

In the light receiving device 1A according to Modification Example 1, the embodiment of the side surfaces 17c of the recess 17 is different from the first embodiment. Specifically, as illustrated in FIG. 5, the first side surface 17c1 and the second side surface 17c2 are inclined in the same direction. The angle θ on the first side surface 17c1 side and the angle θ on the second side surface 17c2 side are both 75° or greater and 105° or less. In the case where the angle θ on the first side surface 17c1 side is 105°, for example, the angle θ on the second side surface 17c2 side is 75°.

Since the first side surface 17c1 and the second side surface 17c2 are inclined in the same direction in Modification Example 1, the recess 17 can be easily formed. Moreover, the light receiving device 1A of Modification Example 1 exhibits the same effects as the light receiving device 1 of the first embodiment.

### Modification Example 2

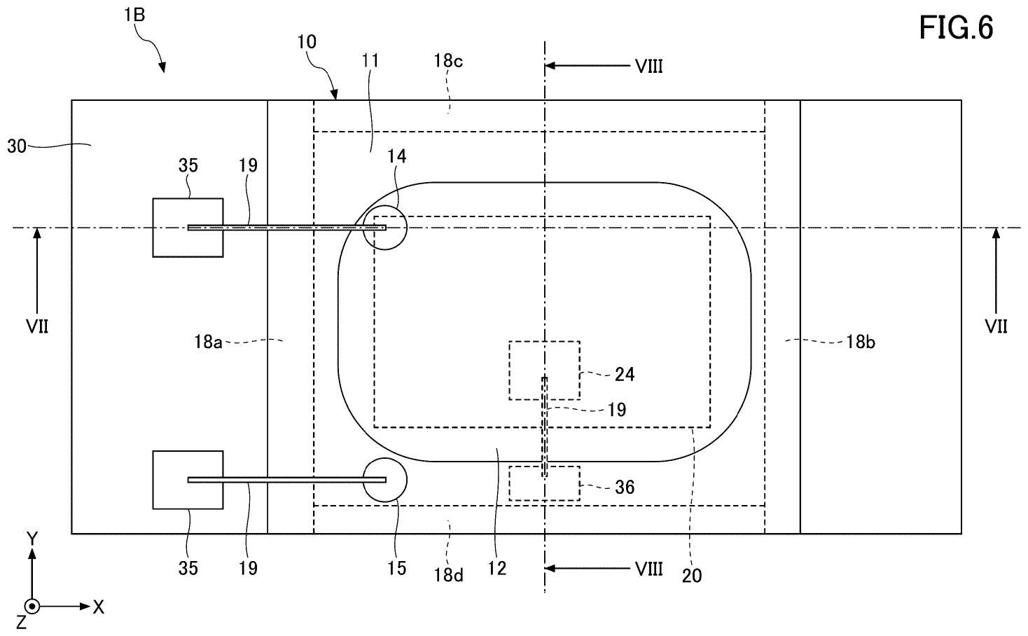

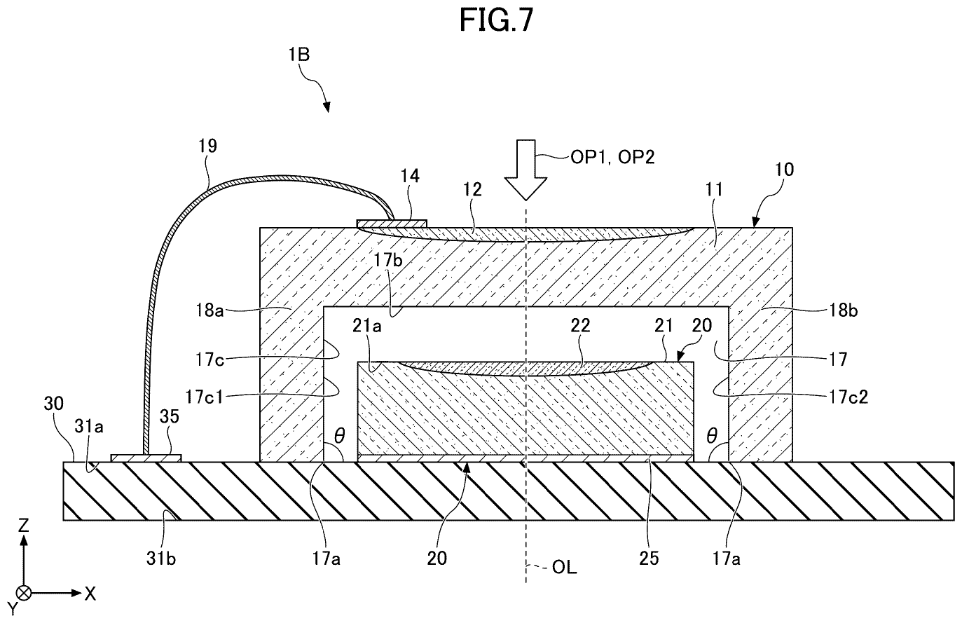

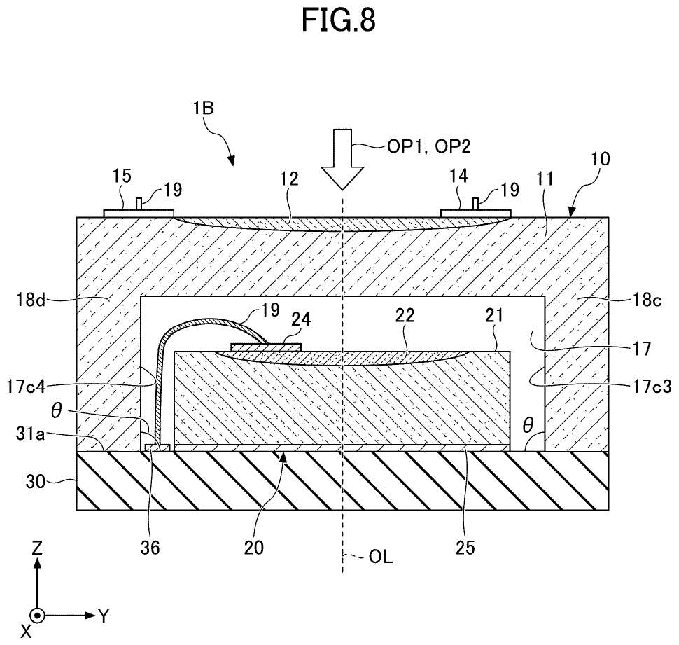

Next, the light receiving device 1B according to Modification Example 2 of the first embodiment will be described with reference to FIGS. 6 to 8. FIG. 6 is a plan view schematically illustrating the light receiving device 1B according to Modification Example 2. FIG. 7 is a cross-sectional view illustrating a schematic cross-section of the light receiving device 1B cut along the line VII-VII of FIG. 6. FIG. 8 is a cross-sectional view illustrating a schematic cross-section of the light receiving device 1B cut along the line VIII-VIII of FIG. 6. Note that the same reference numerals are given to the same constituent components as the constituent components of the first embodiment and Modification Example 1, and redundant description will be appropriately omitted. FIGS. 7 and 8 are an example of cross-sectional views of the light receiving device 1B cut in the perpendicular direction to include the recess 17.

In the light receiving device 1B of Modification Example 2, the first semiconductor substrate 11 is different from the first embodiment in that the first semiconductor substrate 11 has four side walls. Specifically, the first semiconductor substrate 11 includes, in addition to the first side wall 18a and the second side wall 18b facing each other in the X-axial direction, a third side wall 18c and a fourth side wall 18d facing each other in the Y-axial direction.

As illustrated in FIG. 6, the third side wall 18c connects between one edge of the first side wall 18a and one edge of the second side wall 18b. The fourth side wall 18d connects between the other edge of the first side wall 18a and the other edge of the second side wall 18b. The first side wall 18a, the second side wall 18b, the third side wall 18c, and the fourth side wall 18d constitute a frame surrounding the recess 17.

As illustrated in FIG. 7, the angle θ formed between the first side surface 17c1 of the recess 17, which is defined by the inner surface of the first side wall 18a, and the supporting surface 31a, and the angle θ formed between the second side surface 17c2 of the recess 17, which is defined by the inner surface of the second side wall 18b, and the supporting surface 31a are both 75° or greater and 105° or less. As illustrated in FIG. 8, the angle θ formed between the third side surface 17c3 of the recess 17, which is defined by the inner surface of the third side wall 18c, and the supporting surface 31a, and the angle θ formed between the fourth side surface 17c4 of the recess 17, which is defined by the inner surface of the fourth side wall 18d, and the supporting surface 31a are both 75° or greater and 105° or less. The angle θ formed between the third side surface 17c3 of the recess 17 and the supporting surface 31a is an example of the “angle θ3.” The angle θ formed between the fourth side surface 17c4 of the recess 17 and the supporting surface 31a is an example of the “angle θ4.”

Since the angle θ formed between the third side surface 17c3 of the recess 17 an the supporting surface 31a, and the angle θ formed between the fourth side surface 17c4 of the recess 17 and the supporting surface 31a are both 75° or greater and 105° or less in Modification Example 2, the size of the second semiconductor substrate 21 in the X-axial direction and in the Y-axial direction can be increased without increasing the size of the first semiconductor substrate 11 in the X-axial direction and in the Y-axial direction. Thus, an amount of light received by the second light-receiving element 20 can be further increased. Moreover, the light receiving device 1B according to Modification Example 2 exhibits the same effects as the light receiving device 1 according to the first embodiment.

### Second Embodiment

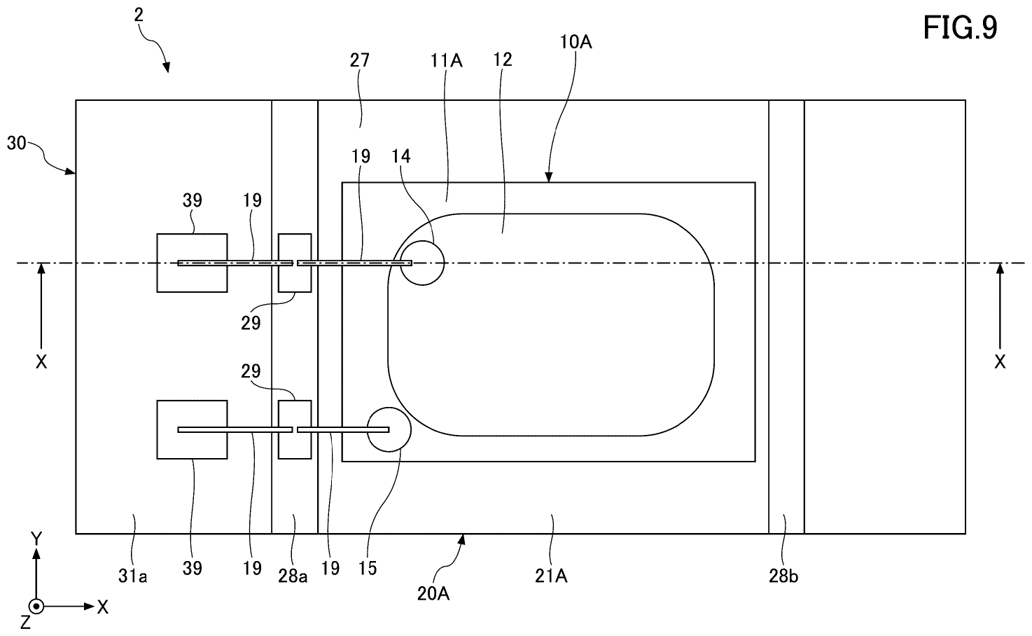

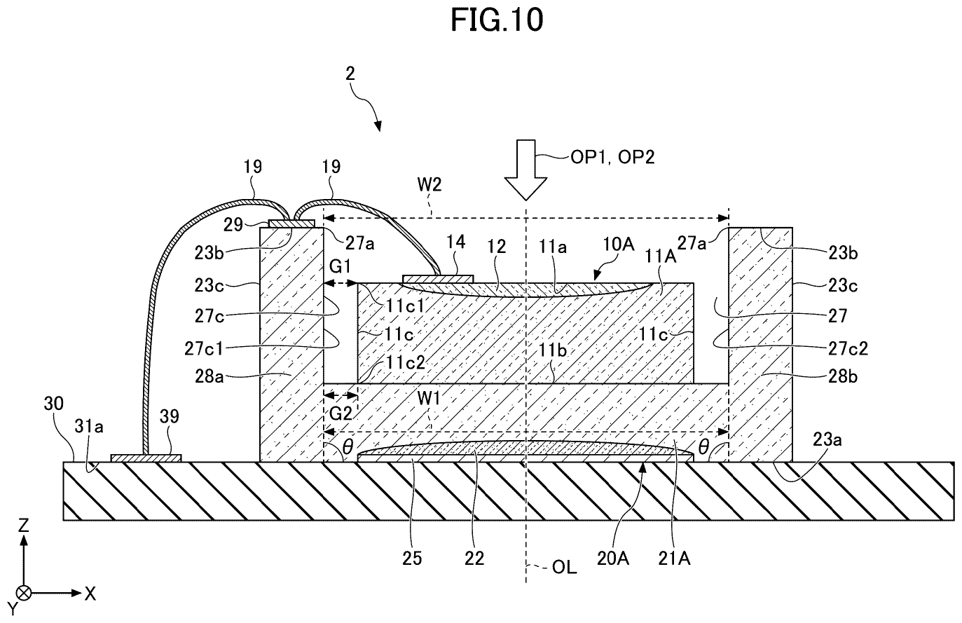

Next, the light receiving device 2 according to the second embodiment will be described with reference to FIGS. 9 and 10. FIG. 9 is a plan view schematically illustrating the light receiving device 2 according to the second embodiment. FIG. 10 is a cross-sectional view illustrating a schematic cross-section of the light receiving device 2 cut along the line X-X of FIG. 9. The same reference numerals are given to the same constituent components as the constituent components of the first embodiment, and Modification Examples 1 and 2 of the first embodiment, and redundant description will be appropriately omitted. FIG. 10 is an example of a cross-sectional view of the light receiving device 2 cut in the perpendicular direction to include the recess 27 of the second light-receiving element 20A, which will be described later.

As illustrated in FIGS. 9 and 10, the light receiving device 2 according to the second embodiment includes a first light-receiving element 10A, a second light-receiving element 20A, and a support substrate 30. The second embodiment is different from the first embodiment in that the second semiconductor substrate 21A of the second light-receiving element 20A has a recess 27. The first semiconductor substrate 11A of the first light-receiving element 10A does not have a recess. The configuration of the first semiconductor substrate 11A and the configuration of the first light-receiving element 10A may be the same as the configuration of the first semiconductor substrate 11 and the configuration of the first light-receiving element 10 of the first embodiment, except that the recess is not provided. In the second embodiment, the second semiconductor substrate 21A is an example of the “semiconductor substrate of the first light-receiving element or the second light-receiving element.” The first semiconductor substrate 11A is an example of “the other semiconductor substrate.”

As illustrated in FIG. 9, the anode 14 and the cathode 15 of the first light-receiving element 10A may be respectively electrically connected to the wiring 39 of the support substrate 30 via a conductive wire, such as a bonding wire 19 or the like, and intermediate wiring 29 provided to the second semiconductor substrate 21A. The wiring 39 is coupled to, for example, an external signal processing circuit.

As illustrated in FIG. 10, the second semiconductor substrate 21A includes a main surface 23a, a back surface 23b, and side surfaces 23c. In the example illustrated in FIG. 10, the main surface 23a corresponds to a surface of the second semiconductor substrate 21A on the −Z side. The back surface 23b is a surface that is on an opposite side of the main surface 23a in the perpendicular direction. Specifically, the back surface 23b corresponds to a surface of the second semiconductor substrate 21A on the +Z side. Each side surface 23c connects an outer edge of the main surface 23a and an outer edge of the back surface 23b.

The second semiconductor substrate 21A further includes a recess 27. The recess 27 corresponds to a hollow space within the second semiconductor substrate 21A, which is sunk from the back surface 23b toward the main surface 23a. In the example illustrated in FIG. 10, the recess 27 includes opening edges 27a on the back surface 23b side of the second semiconductor substrate 21A, a bottom surface 27b that is the −Z side with respect to the opening edges 27a, and side surfaces 27c each being continuous from the opening edge 27a to the bottom surface 27b.

The recess 27 may be formed, for example, by dry etching, a combination of dry etching and wet etching, or machining using a cutting tool, such as a blade or the like. In the second semiconductor substrate 21A, wall-like portions positioned on sides of the recess 27 are formed corresponding to the shape of the recess 27. Each wall-like portion may be referred to as a “side wall” of the second semiconductor substrate 21A hereinafter.

In the example illustrated in FIGS. 9 and 10, the second semiconductor substrate 21A includes, as side walls, a first side wall 28a on the −X side and a second side wall 28b on the +X side. Specifically, in the example illustrated in FIGS. 9 and 10, the second semiconductor substrate 21A includes two side walls. The first side wall 28a and the second side wall 28b face each other with the recess 27 being interposed between the first side wall 28a and the second side wall 28b in the X-axial direction. The recess 27 illustrated in FIGS. 9 and 10 has a gutter-like shape extending in the Y-axial direction, and the gutter-like shape is defined by the first side wall 28a and the second side wall 28b. Specifically, the both ends of the recess 27 in the Y-axial direction are open. The number of the side walls is not limited to two. The number of the side walls may be three or four.

The opening edges 27a are defined by the inner edges of the back surface 23b of the second semiconductor substrate 21A. The bottom surface 27b is defined by the bottom inner surface of the second semiconductor substrate 21A. The bottom surface 27b is, for example, a surface extending in the planar direction. An antireflection film is preferably disposed on the bottom surface 27b. In the example illustrated in FIG. 10, the side surfaces 27c include a first side surface 27c1 on the −X side and a second side surface 27c2 on the +X side. The first side surface 27c1 is defined by the inner surface of the first side wall 28a of the second semiconductor substrate 21A. The second side surface 27c2 is defined by the inner surface of the second side wall 28b of the second semiconductor substrate 21A.

In the cross-sectional view including the recess 27, as illustrated in FIG. 10, when the length of the bottom surface 27b (bottom surface width) is determined as W1, and the length between the opposing opening edges 27a (opening width) is determined as W2, a ratio W1/W2 of W1 to W2 is preferably 0.9 or greater. W1/W2 is more preferably 0.95 or greater. W1/W2 is yet more preferably 1.0 or greater. Also, W1/W2 is preferably 1.1 or less. W1/W2 is more preferably 1.05 or less. Specifically, W1/W2 is preferably 0.9 or greater and 1.1 or less, and more preferably 0.95 or greater and 1.05 or less.

Moreover, the angle θ formed between the side surface 27c of the recess 27 and the supporting surface 31a is 75° or greater and 105° or less. In the example illustrated in FIG. 10, the angle θ formed between the first side surface 27c1 of the recess 27 and the supporting surface 31a is 75° or greater and 105° or less. Moreover, the angle θ formed between the second side surface 27c2 of the recess 27 and the supporting surface 31a is 75° or greater and 105° or less. The angle θ between the first side surface 27c1 of the recess 27 and the supporting surface 31a is an example of the “angle θ1.” The angle θ between the second side surface 27c2 of the recess 27 and the supporting surface 31a is an example of the “angle θ2.” The angle θ between the first side surface 27c1 of the recess 27 and the supporting surface 31a and the angle θ between the second side surface 27c2 of the recess 27 and the supporting surface 31a may be the same or different from each other. In the case where the second semiconductor substrate 21A includes other side walls, among the side surfaces 27c of the recess 27, an angle formed between the side surface region defined by the inner surface of another side wall and the supporting surface 31a is similarly 75° or greater and 105° or less.

Further, a ratio G1/G2 of the gap G1 between the end 11c1 of the side surface 11c of the first semiconductor substrate 11A on the main surface 11a side and the side surface 27c of the recess 27 to the gap G2 between the end 11c2 of the side surface 11c of the first semiconductor substrate 11A on the back surface 11b side and the side surface 27c of the recess 27 is preferably 0.9 or greater and 1.1 or less.

The light receiving device 2 according to the second embodiment exhibits the same effects as the light receiving device 1 according to the first embodiment.

According to one aspect of the present disclosure, the light receiving device can be downsized as described above.

Although the embodiments have been described above, the above embodiments are merely presented as examples, and should not be construed as limiting the scope of the present invention. The above embodiments can be implemented in various other forms, and various combinations, omission, replacements, changes, or the like can be made without departing from the scope of the invention. The embodiments and modifications of the embodiments are included in the scope and spirit of the invention, and are included in the invention described in the claims and the scope of equivalents of the invention described in the claims.

Embodiments of the present disclosure are, for example, as follows.
<1> A light receiving device includes a first light-receiving element that includes a semiconductor substrate including a light receiving region, a second light-receiving element that includes a semiconductor substrate including a light receiving region, and a support substrate that includes a supporting surface supporting the first light-receiving element and the second light-receiving element. The semiconductor substrate of the first light-receiving element or the second light-receiving element includes a main surface including the light receiving region, a back surface that is on an opposite side of the main surface in a perpendicular direction, and a recess that is sunk from the back surface towards the main surface. The other semiconductor substrate of the first light-receiving element or the second light-receiving element is disposed inside the recess. An angle θ formed between a side surface of the recess and the supporting surface is 75° or greater and 105° or less, where the side surface of the recess is a surface continuous from an opening edge of the recess to a bottom surface of the recess.
<2> In the light receiving device according to <1>, a ratio W1/W2 of W1 to W2 is 0.9 or greater and 1.1 or less, where W1 is a length of the bottom surface of the recess and W2 is a length between the opening edge of the recess and an opposing opening edge of the recess in a cross-sectional view of the light receiving device cut in the perpendicular direction.
<3> In the light receiving device according to <1>, the other semiconductor substrate includes a main surface including the light receiving region, a back surface that is an opposite side of the main surface in the perpendicular direction, and a side surface that connects the main surface and the back surface, and faces the side surface of the recess; and a ratio G1/G2 of G1 to G2 is 0.9 or greater and 1.1 or less, where G1 is a gap between an end of the side surface of the other semiconductor substrate on the main surface side and the side surface of the recess, and G2 is a gap between an end of the side surface of the other semiconductor substrate on the back surface side and the side surface of the recess, in a cross-sectional view of the light receiving device cut in the perpendicular direction.
<4> In the light receiving device according to <1> to <3>, the semiconductor substrate of the first light-receiving element or the second light-receiving element includes a first side wall and a second side wall that face each other with the recess being interposed between the first side wall and the second side wall, and the recess includes multiple side surfaces including a first side surface defined by an inner surface of the first side wall and a second side surface defined by an inner surface of the second side wall; an angle θ1 formed between the first side surface and the supporting surface is 75° or greater and 105° or less; and an angle θ2 between the second side surface and the supporting surface is 75° or greater and 105° or less.
<5> In the light receiving device according to <4>, the semiconductor substrate of the first light-receiving element or the second light-receiving element further includes a third side wall and a fourth side wall, where the third side wall connects one edge of the first side wall and one edge of the second side wall, and the fourth side wall connects the other edge of the first side wall and the other edge of the second side wall, and the side surfaces of the recess include a third side surface defined by an inner surface of the third side wall and a fourth side surface defined by an inner surface of the fourth side wall; an angle θ3 formed between the third side surface and the supporting surface is 75° or greater and 105° or less; and an angle θ4 formed between the fourth side surface and the supporting surface is 75° or greater and 105° or less.

What is claimed is:

1. A light receiving device comprising:
a first light-receiving element that includes a semiconductor substrate including a light receiving region;
a second light-receiving element that includes a semiconductor substrate including a light receiving region; and
a support substrate that includes a supporting surface supporting the first light-receiving element and the second light-receiving element,
wherein the semiconductor substrate of the first light-receiving element or the second light-receiving element includes a main surface including the light receiving region, a back surface that is on an opposite side of the main surface in a perpendicular direction, and a recess that is sunk from the back surface towards the main surface,
the other semiconductor substrate of the first light-receiving element or the second light-receiving element is disposed inside the recess, and
an angle θ formed between a side surface of the recess and the supporting surface is 75° or greater and 105° or less, where the side surface of the recess is a surface continuous from an opening edge of the recess to a bottom surface of the recess.

2. The light receiving device according to claim 1,
wherein a ratio W1/W2 of W1 to W2 is 0.9 or greater and 1.1 or less, where W1 is a length of the bottom surface of the recess and W2 is a length between the opening edge of the recess and an opposing opening edge of the recess in a cross-sectional view of the light receiving device cut in the perpendicular direction.

3. The light receiving device according to claim 1,
wherein the other semiconductor substrate includes a main surface including the light receiving region, a back surface that is an opposite side of the main surface in the perpendicular direction, and a side surface that connects the main surface and the back surface, and faces the side surface of the recess, and
wherein a ratio G1/G2 of G1 to G2 is 0.9 or greater and 1.1 or less, where G1 is a gap between an end of the side surface of the other semiconductor substrate on the main surface side and the side surface of the recess, and G2 is a gap between an end of the side surface of the other semiconductor substrate on the back surface side and the side surface of the recess, in a cross-sectional view of the light receiving device cut in the perpendicular direction.

4. The light receiving device according to claim 1,
wherein the semiconductor substrate of the first light-receiving element or the second light-receiving element includes a first side wall and a second side wall that face each other with the recess being interposed between the first side wall and the second side wall, and the recess includes multiple side surfaces including a first side surface defined by an inner surface of the first side wall and a second side surface defined by an inner surface of the second side wall,
wherein an angle θ1 formed between the first side surface and the supporting surface is 75° or greater and 105° or less, and
wherein an angle θ2 between the second side surface and the supporting surface is 75° or greater and 105° or less.

5. The light receiving device according to claim 4,
wherein the semiconductor substrate of the first light-receiving element or the second light-receiving element further includes a third side wall and a fourth side wall, where the third side wall connects one edge of the first side wall and one edge of the second side wall, and the fourth side wall connects the other edge of the first side wall and the other edge of the second side wall, and the side surfaces of the recess include a third side surface defined by an inner surface of the third side wall and a fourth side surface defined by an inner surface of the fourth side wall,
wherein an angle θ3 formed between the third side surface and the supporting surface is 75° or greater and 105° or less, and
wherein an angle θ4 formed between the fourth side surface and the supporting surface is 75° or greater and 105° or less.
